(19) United States
(12) Patent Application Publication
(10) Pub. No.: US 2016/0077151 A1
(43) Pub. Date: Mar. 17, 2016

(54) METHOD AND APPARATUS TO TEST SECURE BLOCKS USING A NON-STANDARD INTERFACE

(71) Applicant: QUALCOMM Incorporated, San Diego, CA (US)

(72) Inventors: Ashutosh Anand, Bangalore (IN); Shankarnarayan Bhat, Bangalore (IN); Arun Balachandar, Bangalore (IN); Nikhil Sudhakaran, Bangalore (IN); Praveen Raghuraman, Bangalore (IN); Devadatta Bhat, Bangalore (IN); Sanjay Muchini, Bangalore (IN)

(21) Appl. No.: 14/484,643

(22) Filed: Sep. 12, 2014

(51) Int. Cl. G01R 31/28

(52) U.S. Cl. CPC G01R 31/2884; G01R 31/2834

(57) ABSTRACT

A method and apparatus for testing secure blocks is provided. The method begins when instructions for testing a secure memory are loaded using a parallel testing interface. Instructions for testing the non-secure memory may be resident on the device as Built-In-Self-Test (BIST) instructions. In that case, the instructions are then accessed through the standard test access. Testing occurs simultaneously for the secure memory and the non-secure memory using both the parallel interface and the standard test interface. Testing both the secure memory blocks and the non-secure memory blocks using the parallel and standard test interfaces saves time during the test process.

### FIELD

The present disclosure relates generally to wireless communication systems, and more particularly to a method and apparatus for testing secure blocks in s chip or system using a non-industry-standard interface.

### BACKGROUND

Wireless communication devices have become smaller and more powerful as well as more capable. Increasingly users rely on wireless communication devices for mobile phone use as well as email and Internet access. At the same time, devices have become smaller in size. Devices such as cellular telephones, personal digital assistants (PDAs), laptop computers, and other similar devices provide reliable service with expanded coverage areas. Such devices may be referred to as mobile stations, stations, access terminals, user terminals, subscriber units, user equipments, and similar terms.

A wireless communication system may support communication for multiple wireless communication devices at the same time. In use, a wireless communication device may communicate with one or more base stations by transmissions on the uplink and downlink. Base stations may be referred to as access points, Node Bs, or other similar terms. The uplink or reverse link refers to the communication link from the wireless communication device to the base station, while the downlink or forward link refers to the communication from the base station to the wireless communication devices.

Wireless communication systems may be multiple access systems capable of supporting communication with multiple users by sharing the available system resources, such as bandwidth and transmit power. Examples of such multiple access systems include code division multiple access (CDMA) systems, time division multiple access (TDMA) systems, frequency division multiple access (FDMA) systems, wideband code division multiple access (WCDMA) systems, global system for mobile (GSM) communication systems, enhanced data rates for GSM evolution (EDGE) systems, and orthogonal frequency division multiple access (OFDMA) systems.

With the wider use of smartphones has also come the need for enhanced security measures. In some devices those enhanced security measures include mechanisms for restricting access to some or all portions of the device. This access restriction may also come into play when the devices are being tested.

Enhanced security measures in many chips, including system-on-chip (SoC) devices used in many mobile devices, restrict access through industry standard interfaces, including testing interfaces. This adversely affects the time needed to test devices and also affects the cost of building the chip or SoC. This restriction limits access to in-modem memory testing through an industry standard test interface. There is a need in the art for a method and apparatus to test secure memory blocks of chips and SoCs using a non-industry-standard test interface.

### SUMMARY

Embodiments contained in the disclosure provide a method and apparatus for testing secure blocks. The method begins when instructions for testing a secure memory are loaded using a parallel testing interface, which in turn brings up the processor to facilitate secure memory access. Testing occurs simultaneously for the secure memory and the non-secure memory using both the parallel interface and the standard test interface.

A further embodiment provides an apparatus for testing a secure memory. The apparatus includes: instructions for testing a secure memory; Built-In-Self-Test (BIST) instructions contained in a modem BIST controller (MBIST). The instructions for testing the secure memory are accessed by the parallel test interface, and the MBIST controller accesses the BIST test functions through the standard test interface.

A still further embodiment provides an apparatus that tests a secure memory. The apparatus includes means for loading instructions for testing a secure memory through a parallel interface; means for accessing instructions for testing a non-secure memory through a standard test interface. The apparatus also includes means for simultaneously testing the secure memory using the parallel test interface and the non-secure memory using the standard test interface.

### BRIEF DESCRIPTION OF THE DRAWINGS

FIG. 1 illustrates a wireless multiple-access communication system, in accordance with certain embodiments of the disclosure.

FIG. 2 is a block diagram of a wireless communication system in accordance with embodiments of the disclosure.

FIG. 3 illustrates an overview of an interface for testing secure blocks using a non-industry-standard interface, in accordance with embodiments of the disclosure.

FIG. 4 is a block diagram of a further embodiment of the disclosure.

FIG. 5 is a chart illustrating the savings of test time when using embodiments of the disclosure.

FIG. 6 is a flowchart of an overview of the testing process when embodiments of the disclosure are utilized.

FIG. 7 is a flowchart of the method of testing secure blocks using a non-industry standard test interface, according to an embodiment of the disclosure.

### DETAILED DESCRIPTION

The detailed description set forth below in connection with the appended drawings is intended as a description of exemplary embodiments of the present invention and is not intended to represent the only embodiments in which the present invention can be practiced. The term “exemplary” used throughout this description means “serving as an example, instance, or illustration,” and should not necessarily be construed as preferred or advantageous over other exemplary embodiments. The detailed description includes specific details for the purpose of providing a thorough understanding of the exemplary embodiments of the invention. It will be apparent to those skilled in the art that the exemplary embodiments of the invention may be practiced without these specific details. In some instances, well-known structures and devices are shown in block diagram form in order to avoid obscuring the novelty of the exemplary embodiments presented herein.

As used in this application, the terms “component,” “module,” “system,” and the like are intended to refer to a computer-related entity, either hardware, firmware, a combination of hardware and software, software, or software in execution. For example, a component may be, but is not limited to being, a process running on a processor, an integrated circuit, a processor, an object, an executable, a thread of execution, a program, and/or a computer. By way of illustration, both an application running on a computing device and the computing device can be a component. One or more components can reside within a process and/or thread of execution and a component may be localized on one computer and/or distributed between two or more computers. In addition, these components can execute from various computer readable media having various data structures stored thereon. The components may communicate by way of local and/or remote processes such as in accordance with a signal having one or more data packets (e.g., data from one component interacting with another component in a local system, distributed system, and/or across a network, such as the Internet, with other systems by way of the signal).

Furthermore, various aspects are described herein in connection with an access terminal and/or an access point. An access terminal may refer to a device providing voice and/or data connectivity to a user. An access wireless terminal may be connected to a computing device such as a laptop computer or desktop computer, or it may be a self-contained device such as a cellular telephone. An access terminal can also be called a system, a subscriber unit, a subscriber station, mobile station, mobile, remote station, remote terminal, a wireless access point, wireless terminal, user terminal, user agent, user device, or user equipment. A wireless terminal may be a subscriber station, wireless device, cellular telephone, PCS telephone, cordless telephone, a Session Initiation Protocol (SIP) phone, a wireless local loop (WLL) station, a personal digital assistant (PDA), a handheld device having wireless connection capability, or other processing device connected to a wireless modem. An access point, otherwise referred to as a base station or base station controller (BSC), may refer to a device in an access network that communicates over the air-interface, through one or more sectors, with wireless terminals. The access point may act as a router between the wireless terminal and the rest of the access network, which may include an Internet Protocol (IP) network, by converting received air-interface frames to IP packets. The access point also coordinates management of attributes for the air interface.

Moreover, various aspects or features described herein may be implemented as a method, apparatus, or article of manufacture using standard programming and/or engineering techniques. The term “article of manufacture” as used herein is intended to encompass a computer program accessible from any computer-readable device, carrier, or media. For example, computer readable media can include but are not limited to magnetic storage devices (e.g., hard disk, floppy disk, magnetic strips . . . ), optical disks (e.g., compact disk (CD), digital versatile disk (DVD) . . . ), smart cards, and flash memory devices (e.g., card, stick, key drive . . . ), and integrated circuits such as read-only memories, programmable read-only memories, and electrically erasable programmable read-only memories.

Various aspects will be presented in terms of systems that may include a number of devices, components, modules, and the like. It is to be understood and appreciated that the various systems may include additional devices, components, modules, etc. and/or may not include all of the devices, components, modules etc. discussed in connection with the figures. A combination of these approaches may also be used.

Other aspects, as well as features and advantages of various aspects, of the present invention will become apparent to those of skill in the art through consideration of the ensuring description, the accompanying drawings and the appended claims.

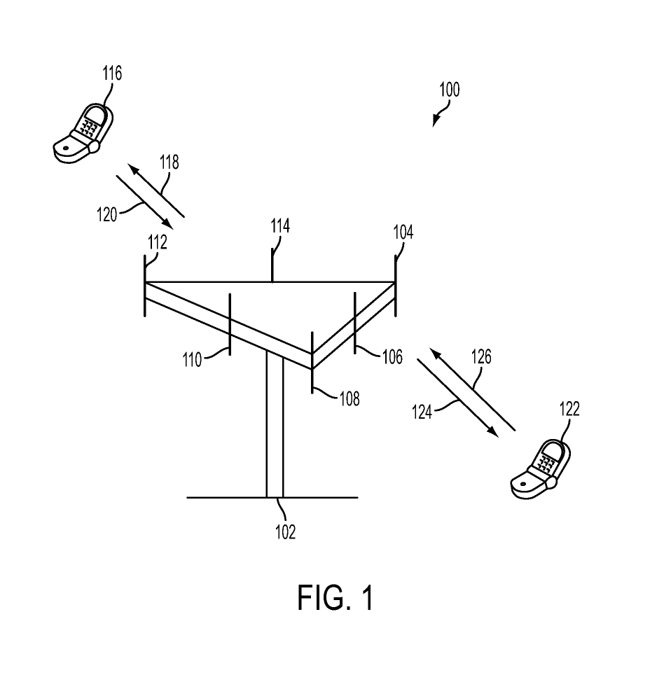

FIG. 1 illustrates a multiple access wireless communication system 100 according to one aspect. An access point 102 (AP) includes multiple antenna groups, one including 104 and 106, another including 108 and 110, and an additional one including 112 and 114. In FIG. 1, only two antennas are shown for each antenna group, however, more or fewer antennas may be utilized for each antenna group. Access terminal 116 (AT) is in communication with antennas 112 and 114, where antennas 112 and 114 transmit information to access terminal 116 over downlink or forward link 118 and receive information from access terminal 116 over uplink or reverse link 120. Access terminal 122 is in communication with antennas 106 and 108, where antennas 106 and 108 transmit information to access terminal 122 over downlink or forward link 124, and receive information from access terminal 122 over uplink or reverse link 126. In a frequency division duplex (FDD) system, communication link 118, 120, 124, and 126 may use a different frequency for communication. For example, downlink or forward link 118 may use a different frequency than that used by uplink or reverse link 120.

Each group of antennas and/or the area in which they are designed to communicate is often referred to as a sector of the access point. In an aspect, antenna groups are each designed to communicate to access terminals in a sector of the areas covered by access point 102.

In communication over downlinks or forward links 118 and 124, the transmitting antennas of an access point utilize beamforming in order to improve the signal-to-noise ration (SNR) of downlinks or forward links for the different access terminals 116 and 122. Also, an access point using beamforming to transmit to access terminals scattered randomly through its coverage causes less interference to access terminals in neighboring cells than an access point transmitting through a single antenna to all its access terminals.

An access point may be a fixed station used for communicating with the terminals and may also be referred to as a Node B, an evolved Node B (eNB), or some other terminology. An access terminal may also be called a mobile station, user equipment (UE), a wireless communication device, terminal or some other terminology. For certain aspects, either the AP 102, or the access terminals 116, 122 may utilize the techniques described below to improve performance of the system.

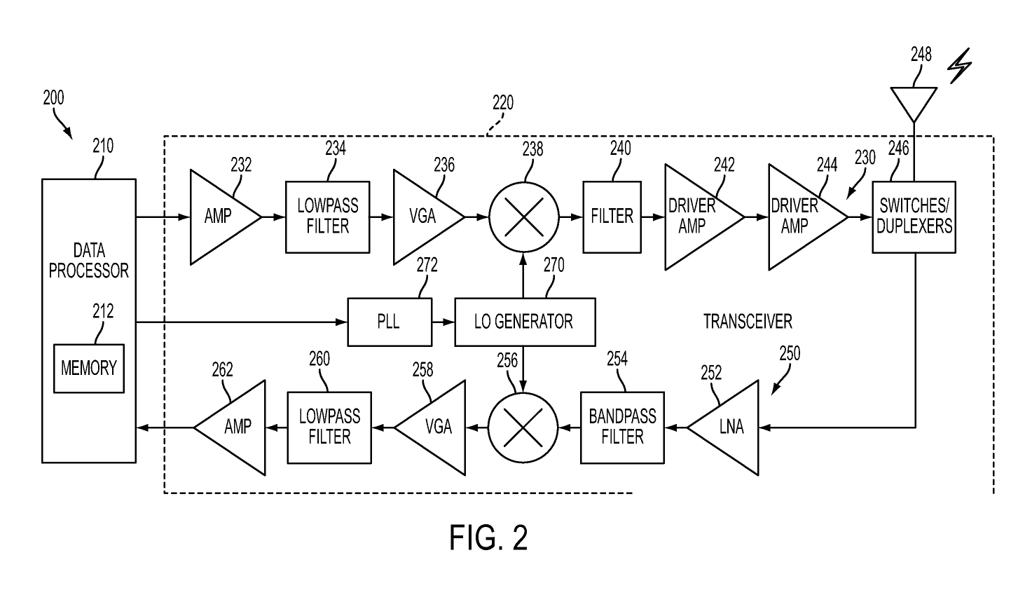

FIG. 2 shows a block diagram of an exemplary design of a wireless communication device 200. In this exemplary design, wireless device 200 includes a data processor 210 and a transceiver 220. Transceiver 220 includes a transmitter 230 and a receiver 250 that support bi-directional wireless communication. In general, wireless device 200 may include any number of transmitters and any number of receivers for any number of communication systems and any number of frequency bands.

In the transmit path, data processor 210 processes data to be transmitted and provides an analog output signal to transmitter 230. Within transmitter 230, the analog output signal is amplified by an amplifier (Amp) 232, filtered by a lowpass filter 234 to remove images caused by digital-to-analog conversion, amplified by a VGA 236, and upconverted from baseband to RF by a mixer 238. The upconverted signal is filtered by a filter 240, further amplified by a driver amplifier, 242 and a power amplifier 244, routed through switches/duplexers 246, and transmitted via an antenna 249.

In the receive path, antenna 248 receives signals from base stations and/or other transmitter stations and provides a received signal, which is routed through switches/duplexers 246 and provided to receiver 250. Within receiver 250, the received signal is amplified by an LNA 252, filtered by a bandpass filter 254, and downconverted from RF to baseband by a mixer 256. The downconverted signal is amplified by a VGA 258, filtered by a lowpass filter 260, and amplified by an amplifier 262 to obtain an analog input signal, which is provided to data processor 210.

FIG. 2 shows transmitter 230 and receiver 250 implementing a direct-conversion architecture, which frequency converts a signal between RF and baseband in one stage. Transmitter 230 and/or receiver 250 may also implement a super-heterodyne architecture, which frequency converts a signal between RF and baseband in multiple stages. A local oscillator (LO) generator 270 generates and provides transmit and receive LO signals to mixers 238 and 256, respectively. A phase locked loop (PLL) 272 receives control information from data processor 210 and provides control signals to LO generator 270 to generate the transmit and receive LO signals at the proper frequencies.

FIG. 2 shows an exemplary transceiver design. In general, the conditioning of the signals in transmitter 230 and receiver 250 may be performed by one or more stages of amplifier, filter, mixer, etc. These circuits may be arranged differently from the configuration shown in FIG. 2. Some circuits in FIG. 2 may also be omitted. All or a portion of transceiver 220 may be implemented on one or more analog integrated circuits (ICs), RF ICs (RFICs), mixed-signal ICs, etc. For example, amplifier 232 through power amplifier 244 in transmitter 230 may also be implemented on an RFIC. Driver amplifier 242 and power amplifier 244 may also be implemented on another IC external to the RFIC.

Data processor 210 may perform various functions for wireless device 200, e.g., processing for transmitter and received data. Memory 212 may store program codes and data for data processor 210. Data processor 210 may be implemented on one or more application specific integrated circuits (ASICs) and/or other ICs.

Mobile devices, such as those described in FIG. 2 rely on processors to perform many of the functions desired by users. As mobile devices perform more functions, the demands on the processors have escalated and processor complexity has increased. Many mobile devices use a single chip, known as a System-on-a-Chip (SoC) to perform the majority of tasks, including running applications. An advanced modem is a key part of the SoC. Some applications require secure data for operation and many mobile service providers store user data and device-specific data in a secure memory or location on the mobile device.

Testing chips and devices with secure memories or memory segments has proven time consuming and difficult. Standard processor testing typically uses an IEEE 1149.1 Interface, also more commonly known as a Joint Test Action Group (JTAG) access port. JTAG ports have become the standard test access ports and may be used with boundary scan architectures. Most commonly, JTAG is used for integrate circuit (IC) debug ports. In the embedded processor marker, essentially all modern processors implement JTAG when sufficient pins are available. Embedded system development relies on debuggers communicating with chips using JTAG to perform operations such as single-stepping and breakpointing. As a result, JTAG has become the industry-standard interface for processor testing.

JTAG was designed to assist with device, board, and system testing, diagnosis, and fault isolation. Today, JTAG is used as the primary means of accessing sub-blocks of integrated circuits. Thus, JTAG has become an essential mechanism for debugging embedded systems which may not have any other debug capable communications channel.

A JTAG adapter uses JTAG as the transport mechanism to access on-chip debug modules inside a target central processing unit (CPU). The debug modules allow debugging the software of an embedded system directly at the machine instruction level when needed, or in terms of high level language source code. Many silicon architectures have built an entire software debug, instruction tracing, and data tracing around the JTAG protocol.

In many ICs, all the pins that connect to an electronic logic are linked together in a set known as the Boundary Scan chain. By using JTAG to manipulate the chip's external interface, it is possible to test for certain faults, caused mainly by manufacturing problems. By using JTAG to manipulate the internal interfaces, the combinational logic may be tested. This testing may be performed after the IC is mounted on a circuit card, and may also be done in a functioning system, when combined with a built in self-test (BIST), the JTAG scan chain allows embedded solution testing of an IC for static faults, such as shorts, opens, and logic errors. These test cases eventually facilitate coverage of secure memory in production testing. A JTAG interface is a special interface added to a chip, and may require additional pins. In some cases, multiple chips on a board may have their JTAG lines daisy-chained together. A test probe need only connect to a single JTAG port to have access to all the chips on a circuit board. Since there is only one test line, JTAG is a serial test interface.

The scenarios described above work well for testing when all components allow the JTAG port access. This is not the case with routines stored in secure memory locations. The security features in advanced modems restrict access by standard test interfaces, including JTAG, as the goal is to maintain the security features during testing. As a result, the memory in secured blocks is untestable and there is no production test coverage. Testing routines or applications stored in secure locations has required a specific debugger be used and run separately from JTAG-based testing. In these cases, test time increases significantly. Other options for testing that access the secure memory regions include having a specific debugger to program memory BIST registers. As chip sizes increase, testing time using only a JTAG interface increases significantly.

Embodiments described herein provide a method for efficiently testing secure memory using a parallel test interface channel (TIC), instead of the JTAG-based SVF. The embodiments provide a parallel configuration of software registers inside a modem. A primary boot processor is brought up at the initiation of the testing process. The digital signal processor (DSP) is then brought up for secure memory access by the parallel interface. Once all processors are up and running the BIST algorithms and test routines are run to test the secure memories. These embodiments provide for testing modem memories, which previously untestable due to the enhanced security features. This method provides a saving in test time. The parallel configuration using the TIC interface is expanded to all other blocks, further enhancing test time improvements.

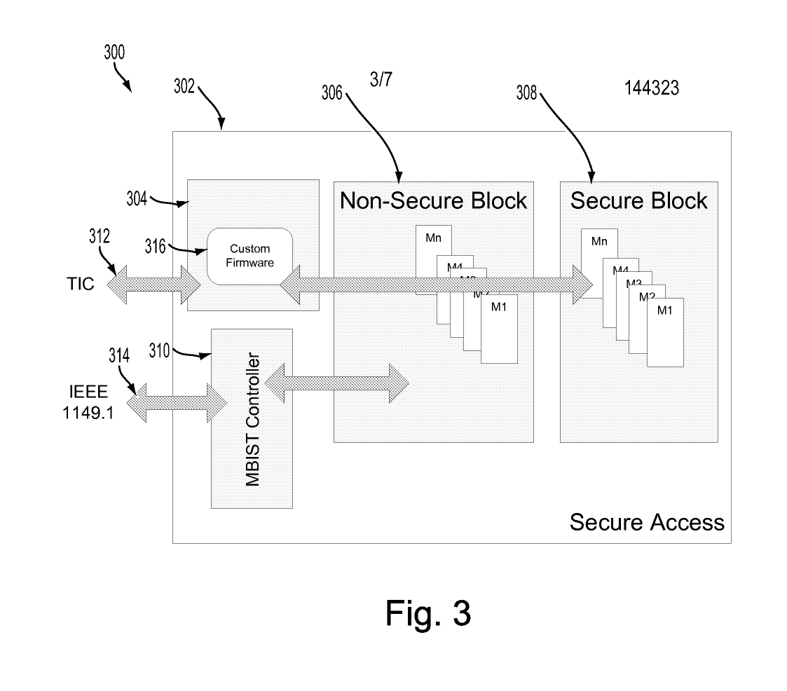

FIG. 3 illustrates in block diagram form an embodiment for testing secure memory using a parallel configuration of software registers inside a modem and a TIC for testing the secure memory block. The assembly, 300 includes a circuit board 302 with chips 304, containing custom firmware 316, a non-secure block of memory 306, and a secure block of memory 308. A modem BIST controller 310, provides testing routines. A TIC 312 provides access to the custom firmware 316 found in chip 304 and is allowed to access secure memory block 308 for testing. A JTAG interface 314 is provided and accesses MBIST controller 310 and non-secure block 306.

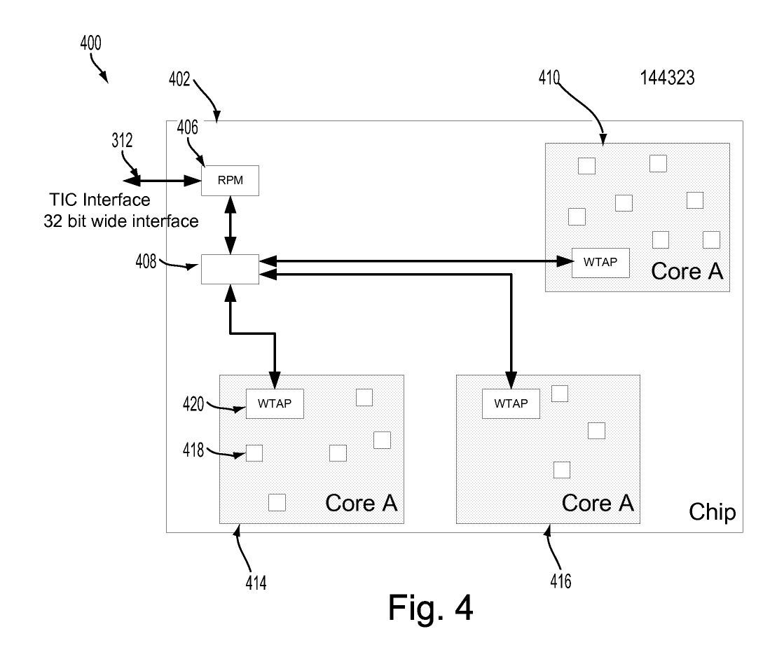

FIG. 4 provides additional detail of a further embodiment of the disclosure. The assembly 400 depicts a circuit board 402 with a number of cores present. A TIC interface 312 provides access to a resource power management module (RPM) 406. TIC interface 312 may be a 32 bit wide interface and may operate at 200MHz, however, other widths and speeds may be used, depending on need. Custom firmware 408 may be provided on a chip, or may be incorporated within a particular processor. Multiple cores 410, 412, and 414 may be provided on circuit board 402. Each core 410, 412, and 414 may incorporate multiple MBIST controllers 418 for testing. Each core 410, 412, and 414 may also incorporate a wireless test access protocol (WTAP) module 420.

In operation, the TIC interface 312 interfaces with RPM module 406. RPM module 406 routes information to the custom firmware 408. The custom firmware provides for routing of the test signals to the wrapper test access ports (WTAPs) located in each core 410, 412, and 414, and also provides for the actuation of the MBIST controllers 418, located within each core. TIC interface 312 writes to multiple 32-bit streams at once, saving time.

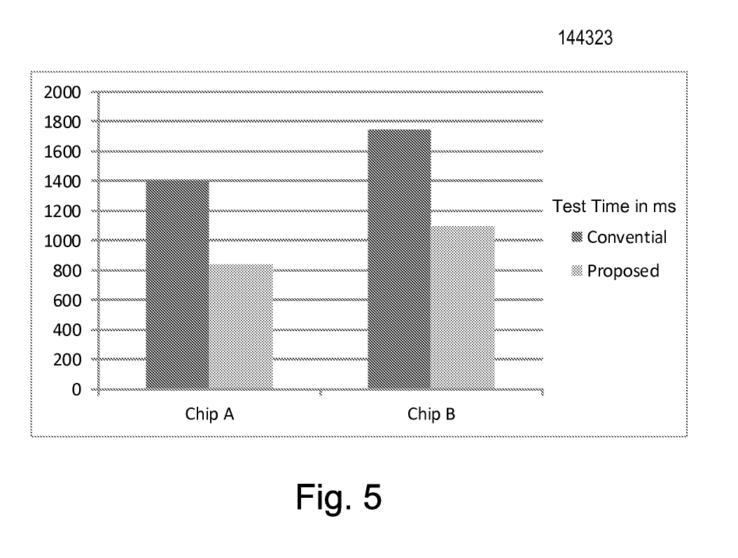

FIG. 5 shows a graphical view of the amount of time saved by testing two different chips, Chip A and Chip B using the methods described herein. For Chip A the time in ms for testing using a conventional interface is approximately 1400 ms, while use the parallel TIC described in the disclosure is only 800 ms, a saving of 600 ms. For more complex Chip B, the time required for testing using a standard interface is approximately 1750 ms, while the same testing carried out using the parallel TIC of the disclosure is approximately 1150 ms is 600 ms. While the test time is small for each device, the difference between the testing interfaces is significant, and becomes more significant when the large number of chips manufactured by many factories is taken into account. In many cases, millions of chips are made each year, and a savings of approximately 600 ms per chip becomes significant with the high production runs.

The advantages of the TIC are significant. The method and apparatus achieve production test coverage without compromising the security of the secure memory blocks. The method is also flexible, and may be implemented to test non-secure memory blocks as well.

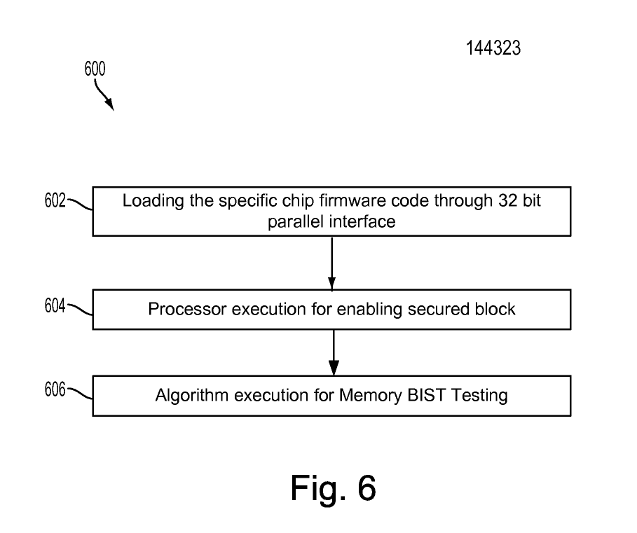

FIG. 6 is a flow diagram of a high-level method of operation of the interface described in this disclosure. The method, 600 begins with step 602 when the firmware code for the particular chip located on the device is loaded through the parallel interface, in this case, a 32 bit parallel interface. In step 604, processor execution for enabling the secured block begins. Once the processor begins executing, the algorithm for the test being run for memory BIST testing starts.

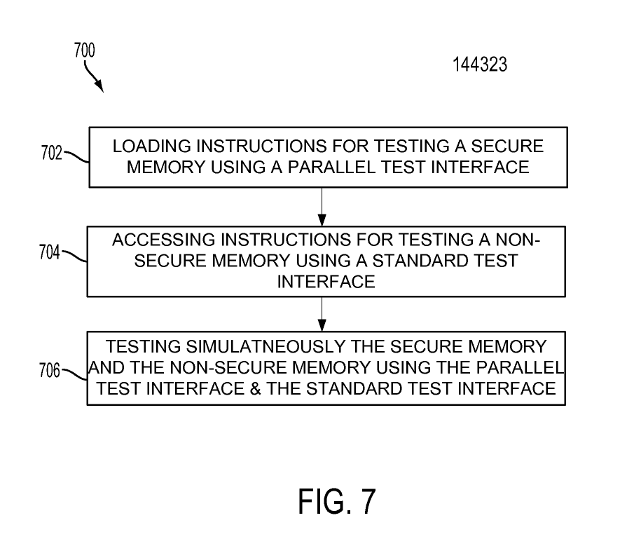

FIG.7 is a flowchart providing additional details of embodiments of the disclosure. The method, 700 begins in step 702 when instructions for testing a secure memory are loaded into a processor as firmware using a parallel test interface. The instructions may also be provided in alternate forms, such as a program loaded onto a controller chip, or other method. Once the instructions for testing the secure memory are loaded, instructions for testing a non-secure memory are accessed using a standard test interface in step 704. These instructions for testing the non-secure memory may be BIST instructions located in a MBIST controller. In the alternative, the instructions may also be loaded using the standard test interface, similar to the loading of the secure memory instructions. Once both sets of instructions are loaded, testing of the secure and non-secure memories proceeds in parallel, with both test interfaces, parallel and standard in operation as shown in step 706.

The standard interface described above may be a JTAG interface, common in the industry, or may be another suitable interface. Typically, the standard interface is an interface that normally operates in a serial mode.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Those of skill would further appreciate that the various illustrative logical blocks, modules, circuits, and algorithm steps described in connection with the exemplary embodiments disclosed herein may be implemented as electronic hardware, computer software, or combinations of both. To clearly illustrate this interchangeability of hardware and software, various illustrative components blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the exemplary embodiments of the invention.

The various illustrative logical blocks, modules, and circuits described in connection with the exemplary embodiments disclosed herein may be implemented or performed with a general purpose processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

In one or more exemplary embodiments, the functions described may be implemented in hardware, software, firmware, or any combination thereof. If implemented in software, the functions may be stored on or transmitter over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM EEPROM, CD-ROM or other optical disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

The previous description of the disclosed exemplary embodiments is provided to enable any person skilled in the art to make or use the invention. Various modifications to these exemplary embodiments will be readily apparent to those skilled in the art, and the generic principles defined herein may be applied to other embodiments without departing from the spirit or scope of the invention. Thus, the present invention is not intended to be limited to the exemplary embodiments shown herein but is to be accorded the widest scope consistent with the principles and novel features disclosed herein.

What is claimed is:

1. A method of testing secure blocks, comprising:
loading instructions for testing a secure memory through a parallel test interface;
accessing instructions for testing a non-secure memory through a standard test interface; and
testing simultaneously the secure memory using the parallel test interface and the non-secure memory using the standard test interface.

2. The method of claim 1, wherein the parallel test interfaces accesses only the secure memory.

3. The method of claim 1, wherein the standard test interface accesses only the non-secure memory.

4. The method of claim 1, further comprising: loading instructions for testing a non-secure memory using the standard test interface.

5. The method of claim 1, wherein the instructions for testing the non-secure memory are Built-In-Self-Test (BIST) instructions pre-loaded onto a core of the device to be tested.

6. An apparatus for testing a secure memory, comprising:
instructions for testing a secure memory;
Built-In-Self-Test (BIST) instructions contained in a modem BIST controller;
a parallel test interface; and
a standard test interface.

7. The apparatus of claim 6, wherein the parallel test interface accesses only the instructions for testing the secure memory.

8. The apparatus of claim 6, wherein the standard test interface accesses only the BIST instructions for testing the non-secure memory.

9. The apparatus of claim 6, wherein the parallel test interface is a 32-bit interface.

10. The apparatus of claim 6, wherein the standard interface is a Joint Test Action Group (JTAG) interface.

11. The apparatus of claim 6, further comprising a modem Built-In-Self-Test controller.

12. The apparatus of claim 6, wherein the secure memory and non-secure memory both reside on a common circuit board.

13. The apparatus of claim 6, wherein the secure memory and non-secure memory both reside on a common chip.

14. An apparatus for testing secure blocks, comprising:
means for loading instructions for testing a secure memory through a parallel interface;
means for accessing instructions for testing a non-secure memory through a standard test interface;
means for testing simultaneously the secure memory using the parallel interface and the non-secure memory using the standard test interface.

15. The apparatus of claim 14, wherein a means for testing the secure memory accesses only the secure memory.

16. The apparatus of claim 14, wherein a means for testing the non-secure memory accesses only the non-secure memory.

17. The apparatus of claim 14, wherein a means for loading instructions for testing a non-secure memory uses the standard test interface.

18. The apparatus of claim 14, wherein a means for loading instructions for testing a non-secure memory loads the instructions from a Built-In-Self-Test controller and the means for loading instructions for testing a secure memory loads instructions using the parallel interface.
